(19) United States
(12) Patent Application Publication
(10) Pub. No.: US 2026/0013090 A1
(43) Pub. Date: Jan. 8, 2026

(54) THERMAL MANAGEMENT SYSTEM FOR ENERGY STORAGE SYSTEM

(71) Applicant: SCS CO., LTD., Sejong-si (KR)

(72) Inventors: Mi Hye KWON, Sejong-si (KR); Hyang Jong HONG, Sejong-si (KR)

(73) Assignee: SCS CO., LTD., Sejong-si (KR)

(21) Appl. No.: 19/257,783

(22) Filed: Jul. 2, 2025

(30) Foreign Application Priority Data
Jul. 3, 2024 (KR) 10-2024-0087790

(51) Int. Cl. H05K 7/20

(52) U.S. Cl. CPC H05K 7/20945; H05K 7/20263; H05K 7/20318; H05K 7/20354; H05K 7/20927; H05K 7/20936

(57) ABSTRACT

Disclosed is a thermal management system for an energy storage system capable of efficiently cooling a battery and a power conversion system with different management temperatures by selectively switching a cooling method according to an outdoor temperature of the energy storage system. A thermal management system for an energy storage system cools a battery and a power conversion system arranged inside the energy storage system by selectively switching a cooling method according to an outdoor temperature of the energy storage system, and includes a first cooling unit that cools the battery and the power conversion system with a first coolant cooled using outside air, and a second cooling unit that cools the battery with a second coolant cooled using a refrigerant.

### CROSS-REFERENCE TO RELATED APPLICATIONS

This application claims the benefit of Korean Patent Application No. 10-2024-0087790, filed on Jul. 3, 2024, in the Korean Intellectual Property Office, the disclosures of which are incorporated herein in their entirety by reference.

### TECHNICAL FIELD

The present disclosure relates to a thermal management system for an energy storage system.

### BACKGROUND

Generally, an energy storage system (ESS) is an energy storage system that stores and manages energy so that energy may be used efficiently.

The energy storage system is an essential technology for effectively utilizing unstable renewable energy such as wind and solar energy, and is receiving attention as a core element of a future energy system.

A similar energy storage system may be utilized in various places and environments such as power plants, transmission and distribution facilities, homes, factories, and businesses, and has the advantage of minimizing power outage damage and saving electricity rates by storing unused electricity and using the stored electricity during times of high demand.

In addition, the energy storage system may store and manage renewable energy such as solar, wind, and hydroelectric power that is irregularly produced, thereby increasing energy utilization efficiency.

Meanwhile, since a large-capacity battery is installed in the energy storage system, heat generation proportional to the capacity of a battery is generated during the energy storage and transmission process.

The heat generation of the battery reduces the life of the battery and the efficiency of energy utilization, and in severe cases, may cause a fire and cause great damage.

Therefore, the development of technology for the heat management technology of the energy storage system to ensure the efficiency and safety of the battery is necessary.

### SUMMARY

The present disclosure was devised to solve the above problems, and an object of the present disclosure provides a thermal management system for an energy storage system capable of efficiently cooling a battery and a power conversion system having different management temperatures by selectively switching a cooling method according to an outdoor temperature of the energy storage system.

Meanwhile, objects of the present disclosure are not limited to the above-mentioned objects. That is, other objects that are not described may be obviously understood by those skilled in the art from the following specification.

According to an aspect of the present disclosure, there is provided a thermal management system for an energy storage system that selectively switches a cooling method according to an outdoor temperature of the energy storage system to cool a battery and a power conversion system (PCS) arranged inside the energy storage system, including: a first cooling unit configured to cool the battery and the power conversion system, or the power conversion system, with a first coolant cooled using outside air; and a second cooling unit configured to cool the battery with a second coolant cooled using a refrigerant.

When an outdoor temperature of the energy storage system is a predetermined temperature or lower, the first cooling unit may sequentially cool the battery and the power conversion system by circulating the first coolant, and when the outdoor temperature of the energy storage system exceeds the predetermined temperature, the first cooling unit may cool the power conversion system by circulating the first coolant, and the second cooling unit may cool the battery by circulating the refrigerant and the second coolant.

The first cooling unit may include: a first coolant storage tank in which the first coolant is stored; a first discharge pump that discharges the first coolant stored in the first coolant storage tank; a radiator that cools the first coolant introduced thereinto using the outside air; a 1-1th coolant flow line that supplies the first coolant discharged from the first discharge pump to the radiator; a 1-2th coolant flow line that supplies the first coolant cooled by the radiator to the battery or the power conversion system; a 1-3th coolant flow line that supplies the first coolant that has passed through the battery to the power conversion system; and a 1-4th coolant flow line that supplies the first coolant that has passed through the power conversion system to the first coolant storage tank.

The 1-2th coolant flow line may supply the first coolant to the battery when the outdoor temperature of the energy storage system is the predetermined temperature or lower, and supply the first coolant to the power conversion system when the outdoor temperature of the energy storage system exceeds the predetermined temperature.

The 1-2th coolant flow line may include: a first supply pipe that is connected to the radiator; a first branch pipe that is branched in a first direction from the first supply pipe and connected to the battery and the second cooling unit; a second branch pipe that is branched in a second direction from the first supply pipe and connected to the power conversion system; and a 1-1th coolant supply control valve that is arranged between the first supply pipe, the first branch pipe, and the second branch pipe, and supplies the first coolant to the first branch pipe or the second branch pipe according to the outdoor temperature of the energy storage system.

The 1-3th coolant flow line may include: a second supply pipe that connects the battery and the power conversion system; and a 1-2th coolant supply control valve that is arranged in the second supply pipe and opens/closes the second supply pipe according to the outdoor temperature of the energy storage system.

The second cooling unit may include: a second coolant storage tank in which the second coolant is stored; a second discharge pump that discharges the second coolant stored in the second coolant storage tank; a heat exchanger that cools the second coolant introduced thereinto using a refrigerant; a 2-1th coolant flow line that supplies the second coolant discharged from the second discharge pump to the heat exchanger; a 2-2th coolant flow line that supplies the second coolant cooled by the heat exchanger to the battery through the first branch pipe; and a 2-3th coolant flow line that supplies the second coolant that has passed through the battery to the second coolant storage tank.

The heat exchanger may include: a compressor for cooling a coolant that compresses a gaseous refrigerant to form a high temperature and high pressure state; a condenser for cooling a coolant that cools the gaseous refrigerant compressed by the compressor for cooling a coolant using the outside air to form the gaseous refrigerant into a liquid state; an expansion valve for cooling a coolant that decompresses the cooled liquid refrigerant and controls a flow rate of the discharged refrigerant to form the refrigerant in a wet vapor state; a chiller for cooling a coolant that heat-exchanges the refrigerant in the decompressed wet vapor with the second coolant flowing inside to cool the second coolant and form the refrigerant into a gaseous state; a first refrigerant flow line that supplies the refrigerant discharged from the compressor for cooling a coolant to the condenser for cooling a coolant; a second refrigerant flow line that supplies the refrigerant discharged from the condenser for cooling a coolant to the expansion valve for cooling a coolant; a third refrigerant flow line that supplies the refrigerant discharged from the expansion valve for cooling a coolant to the chiller for cooling a coolant; and a fourth refrigerant flow line that supplies the refrigerant discharged from the chiller for cooling a coolant to the compressor for cooling a coolant.

The radiator and the condenser for cooling a coolant may be arranged to overlap each other and simultaneously cooled by the outside air.

The 2-2th coolant flow line may include: a third supply pipe that connects the heat exchanger and the first branch pipe; and a 2-1th coolant supply control valve that is arranged between the third supply pipe and the first branch pipe and opens/closes the third supply pipe according to the outdoor temperature of the energy storage system.

The 2-3th coolant flow line may include: a fourth supply pipe that connects the battery and the second coolant storage tank; and a 2-2th coolant supply control valve that is arranged in the fourth supply pipe and opens/closes the fourth supply pipe according to the outdoor temperature of the energy storage system.

The thermal management system may further include: a dehumidifier that controls an internal humidity of a specific zone of the energy storage system, in which the dehumidifier is connected to one section of the first cooling unit, and releases heat generated during dehumidification by exchanging heat with the first coolant flowing in the first cooling unit.

The dehumidifier may include: a compressor for dehumidification that compresses a gaseous dehumidifying refrigerant to form a high temperature and high pressure state; a condenser for dehumidification that is connected to one section of the 1-1th coolant flow line and cools the gaseous dehumidifying refrigerant compressed by the compressor for dehumidification by exchanging heat with the first coolant to form the gaseous dehumidifying refrigerant into a liquid state; an expansion valve for dehumidification that decompresses the cooled liquid dehumidifying refrigerant and controls a flow rate of the discharged dehumidifying refrigerant to form the dehumidifying refrigerant in a wet vapor state; an evaporator for dehumidification that heat exchanges the dehumidifying refrigerant in the decompressed wet vapor state with air flowing inside the energy storage system to remove moisture from the air, and form the dehumidifying refrigerant into a gaseous state; a drain unit that discharges the moisture separated from the air by the evaporator for dehumidification to the outside of the energy storage system; and a fan for dehumidification that is arranged in front of the evaporator for dehumidification and introduces air flowing inside the energy storage system into the evaporator for dehumidification, and discharges dried air passing through the evaporator for dehumidification back into the inside of the energy storage system.

The specific zone where the dehumidifier controls the internal humidity may be a zone including at least one of a PCS room equipped with the power conversion system or a battery room equipped with the battery.

The predetermined temperature may be set to 20° C.

### BRIEF DESCRIPTION OF THE DRAWINGS

FIG. 1 is a conceptual diagram schematically illustrating a thermal management system according to an embodiment of the present disclosure.

FIG. 2 is a diagram illustrating a cooling cycle of the thermal management system when an outdoor temperature of the energy storage system is 20° C. or lower.

FIG. 3 is a diagram illustrating the cooling cycle of the thermal management system when the outdoor temperature of the energy storage system exceeds 20° C.

FIG. 4 is a conceptual diagram schematically illustrating the thermal management system in which a condenser and a radiator for cooling a coolant are arranged in a parallel structure.

FIG. 5 is a conceptual diagram schematically illustrating the thermal management system in which a plurality of condensers and radiators for cooling a coolant are arranged in a parallel structure.

### DETAILED DESCRIPTION OF EMBODIMENTS

Hereinafter, embodiments will be described in detail with reference to the accompanying drawings. However, embodiments may be modified in various ways, and the scope of the patent application is not limited or restricted by these embodiments. It should be understood that all modifications, equivalents, or substitutes for the embodiments are included in the scope of the rights.

Specific structural or functional descriptions of embodiments are disclosed for illustrative purposes only and may be modified and implemented in various forms. Therefore, embodiments are not limited to specific disclosed forms, and the scope of the present specification includes modifications, equivalents, or substitutes included in the technical idea.

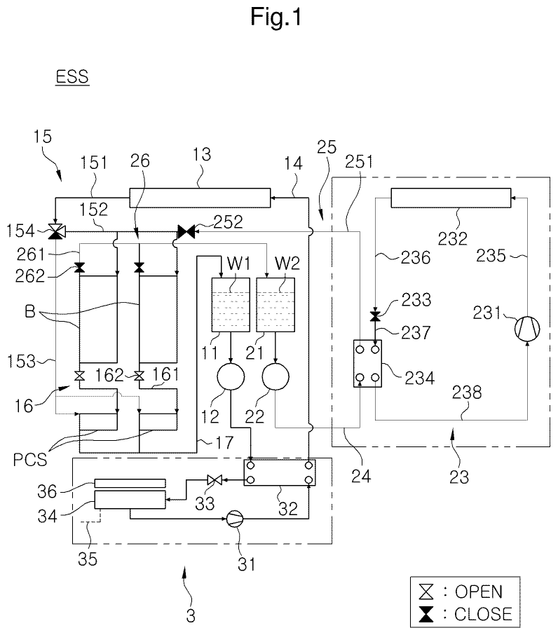

FIG. 1 is a conceptual diagram schematically illustrating a thermal management system according to an embodiment of the present disclosure.

Referring to FIG. 1, a thermal management system (hereinafter referred to as the “thermal management system”) of an energy storage system (ESS) according to an embodiment of the present disclosure selectively switches a cooling method according to an outdoor temperature of the energy storage system (ESS) to cool the battery B and the power conversion system (PCS) arranged inside the energy storage system (ESS).

Here, the battery B refers to a battery cooling means that is equipped with batteries B, and directly cools the batteries B by being in contact with the batteries B or indirectly cools the batteries B by being spaced apart from the batteries B. The power conversion system (PCS) refers to a power conversion system cooling means that is equipped with the power conversion systems (PCS), and directly cools the power conversion systems (PCS) by contacting the power conversion systems (PCS) or indirectly cools the power conversion systems (PCS) by being spaced from the power conversion systems (PCS).

The thermal management system may be configured to include a first cooling unit 1 and a second cooling unit 2.

The first cooling unit 1 cools the battery B and the power conversion system (PCS) with a first coolant W1 cooled using outside air, and the second cooling unit 2 cools the battery B with a second coolant W2 cooled using a refrigerant.

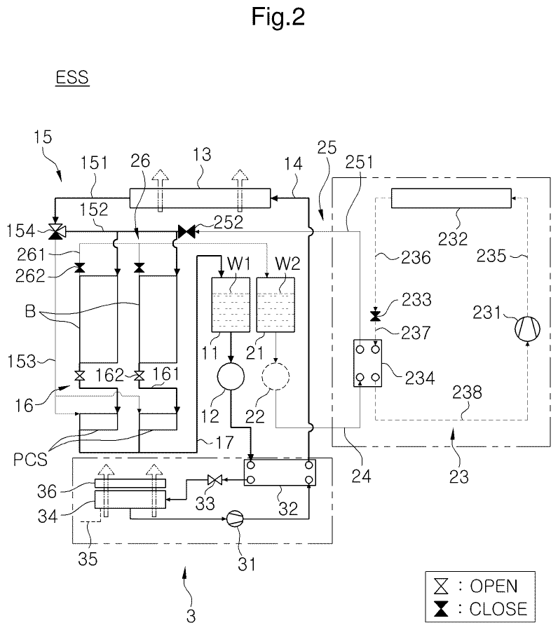

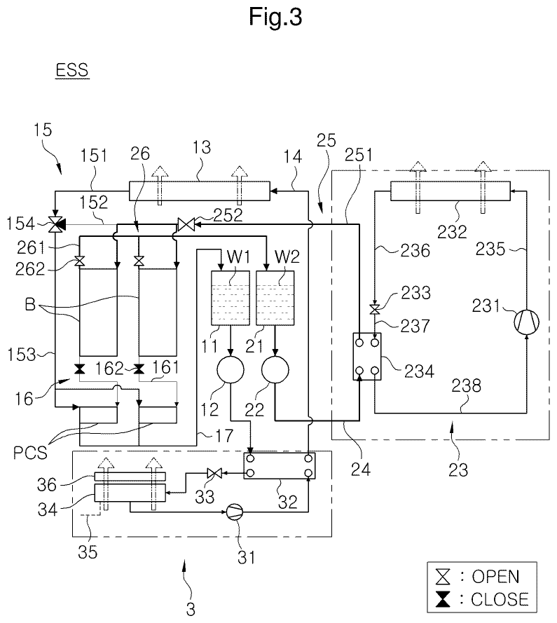

FIG. 2 is a diagram illustrating a cooling cycle of the thermal management system when the outdoor temperature of the energy storage system is a predetermined temperature or lower, and FIG. 3 is a diagram illustrating the cooling cycle of the thermal management system when the outdoor temperature of the energy storage system exceeds a predetermined temperature.

Referring to FIGS. 2 and 3, the first cooling unit 1 may operate to sequentially cool the battery B and the power conversion system (PCS) or to cool only the power conversion system (PCS) according to the outdoor temperature of the energy storage system (ESS).

More specifically, the first cooling unit 1 sequentially cools the battery B and the power conversion system (PCS) by circulating the first coolant W1 as illustrated in FIG. 2 when the outdoor temperature of the energy storage system (ESS) is the predetermined temperature or lower, and cools the power conversion system (PCS) by circulating the first coolant W1 as illustrated in FIG. 3 when the outdoor temperature of the energy storage system (ESS) exceeds the predetermined temperature.

In this case, the second cooling unit 2 may not operate or may operate to cool only the battery B according to the outdoor temperature of the energy storage system (ESS).

More specifically, the second cooling unit 2 does not operate as illustrated in FIG. 2 when the outdoor temperature of the energy storage system (ESS) is the predetermined temperature or lower, and cools the battery B by circulating the coolant and the second coolant W2 as illustrated in FIG. 3 when the outdoor temperature of the energy storage system (ESS) exceeds the predetermined temperature.

That is, since the battery B and the power conversion system (PCS) have different management temperatures, the thermal management system may selectively switch the cooling method according to the outdoor temperature of the energy storage system (ESS) and perform the cooling.

For reference, the management temperature of the battery B is 23 to 27° C., and the management temperature of the power conversion system (PCS) is 40 to 50° C.

The predetermined temperature of the outside air at which the operation of the first and second cooling units 1 and 2 is controlled according to the outdoor temperature may be appropriately set to a lower value by referring to the allowable management temperature of the battery B, but for the convenience of explanation, the following explanation will assume the case where the predetermined temperature of the outside air at which the operation of the first and second cooling units 1 and 2 is controlled is 20° C.

First, the thermal management system of the present disclosure may cool the first coolant W1 to a temperature sufficient to cool the battery B using the outside air when the outdoor temperature of the energy storage system (ESS) is 20° C. or lower, and thus may operate to sequentially cool the battery B and the power conversion system (PCS) using the first coolant W1.

In this case, since the management temperature of the power conversion system (PCS) is relatively higher compared to that of the battery B, the power conversion system (PCS) may be cooled by the first coolant W1 that has passed through the battery B.

In addition, since it is difficult to sufficiently cool the first coolant W1 to the management temperature of the battery B using the outside air when the outdoor temperature of the energy storage system (ESS) exceeds 20° C., the thermal management system may operate to cool the battery B with a relatively low management temperature using the second coolant W2, and to cool the power conversion system (PCS) with a relatively high management temperature using the first coolant W1.

For reference, the first cooling unit 1 may cool the first coolant W1 to the outdoor temperature of the energy storage system (ESS) of 40° C. using the outside air. In this case, the second coolant W2 may be cooled by the refrigerant and have a sufficiently low temperature to cool the battery B.

The first cooling unit 1 may include a first coolant storage tank 11, a first discharge pump 12, a radiator 13, a 1-1th coolant flow line 14, a 1-2th coolant flow line 15, a 1-3th coolant flow line 16, and a 1-4th coolant flow line 17.

The first coolant storage tank 11 may store the first coolant W1 inside.

For example, a level sensor that detects a level of the first coolant W1 stored inside may be arranged in the first coolant storage tank 11.

The first discharge pump 12 is connected to the first coolant storage tank 11 and may discharge the first coolant W1 stored in the first coolant storage tank 11.

The radiator 13 may cool the first coolant W1 introduced thereinto using the outside air.

In this case, a cooling fan may be arranged in front or rear of the radiator 13 to cool the first coolant W1 flowing in the radiator 13 by flowing the outside air.

The 1-1th coolant flow line 14 connects the first discharge pump 12 and the radiator 13, and supplies the first coolant W1 discharged from the first discharge pump 12 to the radiator 13.

For example, a temperature sensor that detects the temperature of the first coolant W1 flowing thereinto may be arranged in the 1-1th coolant flow line 14.

The 1-2th coolant flow line 15 may connect the radiator 13 and the battery B, and connect the radiator 13 and the power conversion system (PCS).

The 1-2th coolant flow line 15 may supply the first coolant W1 cooled by the radiator 13 to the battery B or the power conversion system (PCS) according to the outdoor temperature of the energy storage system (ESS).

More specifically, the 1-2th coolant flow line 15 may supply the first coolant W1 to the battery B when the outdoor temperature of the energy storage system (ESS) is 20° C. or lower, and may supply the first coolant W1 to the power conversion system (PCS) when the outdoor temperature of the energy storage system (ESS) exceeds 20° C.

The 1-2th coolant flow line 15 may include a first supply pipe 151, a first branch pipe 152, a second branch pipe 153, and a 1-1th coolant supply control valve 154.

The first supply pipe 151 connects the radiator 13 and the 1-1th coolant supply control valve 154, and may supply the first coolant W1 cooled through the radiator 13 to the 1-1th coolant supply control valve 154.

The first branch pipe 152 may branch from the first supply pipe 151 in the first direction, and may be connected to the battery B and the second cooling unit 2.

More specifically, the first branch pipe 152 may connect the 1-1th coolant supply control valve 154 and the battery B, and connect the battery B and the second cooling unit 2.

The second branch pipe 153 may branch from the first supply pipe 151 in the second direction and be connected to the power conversion system (PCS).

More specifically, the second branch pipe 153 may connect the 1-1th coolant supply control valve 154 and the power conversion system (PCS).

The 1-1th coolant supply control valve 154 may be arranged between the first supply pipe 151, the first branch pipe 152, and the second branch pipe 153.

The 1-1th coolant supply control valve 154 may supply the first coolant W1 to the first branch pipe 152 or the second branch pipe 153 according to the outdoor temperature of the energy storage system (ESS).

More specifically, the 1-1th coolant supply control valve 154 may open the first branch pipe 152 and close the second branch pipe 153 to supply the first coolant W1 to the first branch pipe 152 when the outdoor temperature of the energy storage system (ESS) is 20° C. or lower. The 1-1th coolant supply control valve 154 may open the second branch pipe 153 and close the first branch pipe 152 to supply the first coolant W1 to the second branch pipe 153 when the outdoor temperature of the energy storage system (ESS) exceeds 20° C.

For example, the 1-1th coolant supply control valve 154 may be a three-way valve. The temperature sensor that detects the temperature of the first coolant W1 flowing inside each of the first supply pipe 151, the first branch pipe 152, and the second branch pipe 153 may be arranged.

The 1-3th coolant flow line 16 connects the battery B and the power conversion system (PCS), and may supply the first coolant W1 passing through the battery B to the power conversion system (PCS).

The 1-3th coolant flow line 16 may include a second supply pipe 161 and a 1-2th coolant supply control valve 162.

The second supply pipe 161 may connect the battery B and the power conversion system (PCS).

The 1-2th coolant supply control valve 162 is arranged in one section of the second supply pipe 161, and may open/close the second supply pipe 161 according to the outdoor temperature of the energy storage system (ESS).

More specifically, the 1-2th coolant supply control valve 162 may open the second supply pipe 161 when the outdoor temperature of the energy storage system (ESS) is 20° C. or lower, and close the second supply pipe 161 when the outdoor temperature of the energy storage system (ESS) exceeds 20° C.

For example, the 1-2th coolant supply control valve 162 may be a two-way valve. In addition, the temperature sensor that detects the temperature of the first coolant W1 flowing inside the second supply pipe 161 may be arranged.

The 1-4th coolant flow line 17 connects the power conversion system (PCS) and the first coolant storage tank 11, and may supply the first coolant W1 passing through the power conversion system (PCS) to the first coolant storage tank 11.

For example, the temperature sensor that detects the temperature of the first coolant W1 flowing inside may be arranged in the 1-4th coolant flow line 17.

Therefore, as illustrated in FIG. 2, when the outdoor temperature of the energy storage system (ESS) is 20° C. or lower, the first coolant W1 discharged from the first coolant storage tank 11 through the first discharge pump 12 flows into the radiator 13 through the 1-1th coolant flow line 14 and is cooled by the outside air. Then, the first coolant W1 cooled in the radiator 13 flows into the battery B through the 1-2th coolant flow line 15 and cools the battery B. In addition, the first coolant W1 that has cooled the battery B flows into the power conversion system (PCS) through the 1-3th coolant flow line 16 to cool the power conversion system (PCS) The first coolant W1 that has cooled the power conversion system (PCS) flows into the first coolant storage tank 11 through the 1-4th coolant flow line 17.

Referring to FIG. 3, the second cooling unit 2 may include a second coolant storage tank 21, a second discharge pump 22, a heat exchanger 23, a 2-1th coolant flow line 24, a 2-2th coolant flow line 25, and a 2-3th coolant flow line 26.

The second coolant storage tank 21 may store the second coolant W2 inside.

For example, the level sensor that detects the level of the second coolant W2 stored inside may be arranged the second coolant storage tank 21.

The second discharge pump 22 may discharge the second coolant W2 stored in the second coolant storage tank 21.

The heat exchanger 23 may cool the second coolant W2 introduced into the interior using a refrigerant.

The heat exchanger 23 may include a compressor 231 for cooling a coolant, a condenser 232 for cooling a coolant, an expansion valve 233 for cooling a coolant 233, a chiller 234 for cooling a coolant, a first refrigerant flow line 235, a second refrigerant flow line 236, a third refrigerant flow line 237, and a fourth refrigerant flow line 238.

The compressor 231 for cooling a coolant may compress a gaseous refrigerant to form the gaseous refrigerant into a high temperature and high pressure state.

The condenser 232 for cooling a coolant may cool the gaseous refrigerant compressed by the compressor 231 for cooling a coolant using the outside air to form the gaseous refrigerant into a liquid state.

In this case, a cooling fan may be arranged in front or rear of the condenser 232 for cooling a coolant to cool the refrigerant flowing in the condenser 232 for cooling a coolant by flowing the outside air.

The expansion valve 233 for cooling a coolant may reduce the pressure of the cooled liquid refrigerant and control the flow rate of the discharged refrigerant to form the refrigerant in a wet vapor state.

The chiller 234 for cooling a coolant may cool the second coolant W2 by exchanging heat with the second coolant W2 flowing inside the decompressed refrigerant in the wet vapor state and form the refrigerant into the gaseous state. The first refrigerant flow line 235 connects the compressor 231 for cooling a coolant 231 and the condenser 232 for cooling a coolant, and may supply the refrigerant discharged from the compressor 231 for cooling a coolant to the condenser 232 for cooling a coolant.

The second refrigerant flow line 236 connects the condenser 232 for cooling a coolant and the expansion valve 233 for cooling a coolant, and may supply the refrigerant discharged from the condenser 232 for cooling a coolant to the expansion valve 233 for cooling a coolant.

The third refrigerant flow line 237 connects the expansion valve 233 for cooling a coolant and the chiller 234 for cooling a coolant, and may supply the refrigerant discharged from the expansion valve 233 for cooling a coolant to the chiller 234 for cooling a coolant.

The fourth refrigerant flow line 238 connects the chiller 234 for cooling a coolant and the compressor 231 for cooling a coolant, and may supply the refrigerant discharged from the chiller 234 for cooling a coolant to the compressor 231 for cooling a coolant.

For example, the temperature sensor that detects the temperature of the refrigerant flowing inside each of the first refrigerant flow line 235, the second refrigerant flow line 236, the third refrigerant flow line 237, and the fourth refrigerant flow line 238 may be arranged.

The 2-1th coolant flow line 24 connects the second discharge pump 22 and the heat exchanger 23, and may supply the second coolant W2 discharged from the second discharge pump 22 to the heat exchanger 23.

For example, the temperature sensor that detects the temperature of the second coolant W2 flowing inside may be arranged in the 2-1th coolant flow line 24.

The 2-2th coolant flow line 25 connects the heat exchanger 23 and the first branch pipe 152, and may supply the second coolant W2 cooled by the heat exchanger 23 to the battery B through the first branch pipe 152.

The 2-2th coolant flow line 25 may include a third supply pipe 251 and a 2-1th coolant supply control valve 252.

The third supply pipe 251 may connect the heat exchanger 23 and the first branch pipe 152.

More specifically, the third supply pipe 251 may connect the heat exchanger 23 and the 2-1th coolant supply control valve 252.

The 2-1th coolant supply control valve 252 is arranged between the third supply pipe 251 and the first branch pipe 152, and may open/close the third supply pipe 251 according to the outdoor temperature of the energy storage system (ESS).

More specifically, the 2-1th coolant supply control valve 252 may close the third supply pipe 251 when the outdoor temperature of the energy storage system (ESS) is 20° or lower, and open the third supply pipe 251 when the outdoor temperature of the energy storage system (ESS) exceeds 20° C.

For example, the 2-1th coolant supply control valve 252 may be the two-way valve. In addition, the temperature sensor that detects the temperature of the second coolant W2 flowing inside may be arranged in the third supply pipe 251.

The 2-3th coolant flow line 26 connects the battery B and the second coolant storage tank 21, and may supply the second coolant W2 passing through the battery B to the second coolant storage tank 21.

The 2-3th coolant flow line 26 may include a fourth supply pipe 261 and a 2-2th coolant supply control valve 262.

The fourth supply pipe 261 may connect the battery B and the second coolant storage tank 21.

The 2-2th coolant supply control valve 262 is arranged in one section of the fourth supply pipe 261, and may open and close the fourth supply pipe 261 according to the outdoor temperature of the energy storage system (ESS).

More specifically, the 2-2th coolant supply control valve 262 may close the fourth supply pipe 261 when the outdoor temperature of the energy storage system (ESS) is 20° C. or lower, and open the fourth supply pipe 261 when the outdoor temperature of the energy storage system (ESS) exceeds 20° C.

For example, the 2-2th coolant supply control valve 262 may be the two-way valve. In addition, the temperature sensor that detects the temperature of the second coolant W2 flowing inside may be arranged in the fourth supply pipe 261.

Therefore, as illustrated in FIG. 3, when the outdoor temperature of the energy storage system (ESS) exceeds 20° C., the second coolant W2 discharged from the second coolant storage tank 21 through the second discharge pump 22 flows into the heat exchanger 23 through the 2-1th coolant flow line 24 and is cooled by the refrigerant of the heat exchanger 23. In addition, the second coolant W2 cooled in the heat exchanger 23 flows into the first branch pipe 152 through the 2-2th coolant flow line 25 and then flows into the battery B to cool the battery B. In addition, the second coolant W2 that cools the battery B flows into the second coolant storage tank 21 through the 2-3th coolant flow line 26.

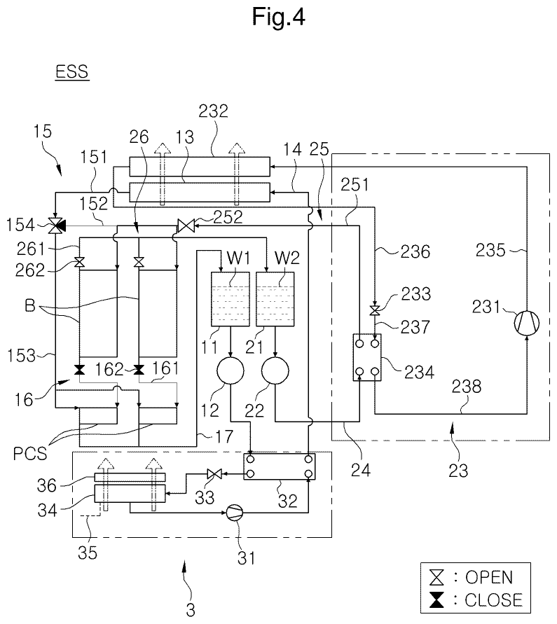

FIG. 4 is a conceptual diagram schematically illustrating the thermal management system in which the condenser for cooling a coolant and the radiator are arranged in a parallel structure.

Meanwhile, the radiator 13 of the first cooling unit 1 and the condenser 232 for cooling a coolant of the heat exchanger 23 may be arranged in series as illustrated in FIG. 1 or may be arranged in parallel while overlapping each other as illustrated in FIG. 4, according to the installation environment.

In this case, the condenser 232 for cooling a coolant may be arranged on the top of the radiator 13 or in front of the radiator 13 along the direction in which the outside air flows.

In addition, the radiator 13 and the condenser 232 for cooling a coolant arranged in parallel while overlapping each other may be cooled simultaneously by the outside air.

In this case, the cooling fan may be arranged in front or rear of the radiator 13 to introduce the outside air and discharge the outside air toward the radiator 13 and the condenser 232 for cooling a coolant.

Therefore, the outside air introduced into the rear of the radiator 13 and discharged to the front may simultaneously cool the first coolant W1 flowing in the radiator 13 and the refrigerant flowing in the condenser 232 for cooling a coolant while sequentially passing through the radiator 13 and the condenser 232 for cooling a coolant.

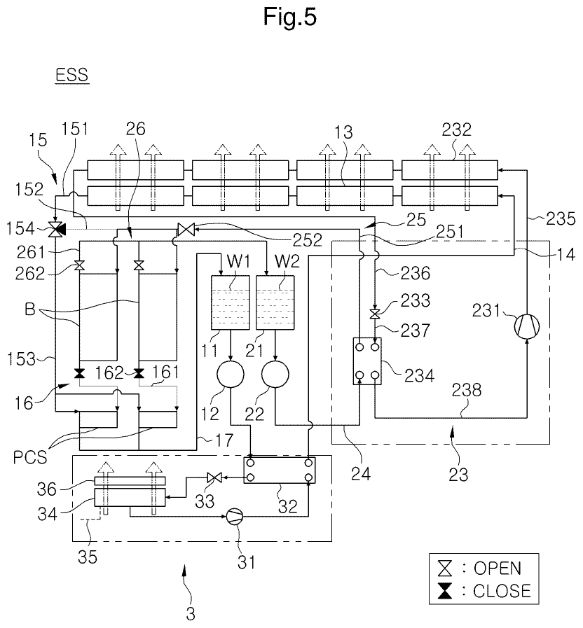

FIG. 5 is a conceptual diagram schematically illustrating the thermal management system in which the condenser for cooling a coolant and the radiators are arranged in plurality in a parallel structure.

Meanwhile, referring to FIG. 5, the radiator 13 and the condenser 232 for cooling a coolant arranged in the parallel structure may be arranged in plurality according to the capacity of the energy storage system (ESS).

Referring to FIG. 1, the thermal management system may further include a dehumidifier 3.

The dehumidifier 3 may be a configuration that controls an internal humidity of a specific zone of the energy storage system (ESS).

Here, the specific zone may be the entire energy storage system (ESS) as a zone requiring control of the internal humidity through the dehumidification, but may also be a PCS room equipped with a power conversion system, a battery room equipped with a battery, or a zone equipped with both the power conversion system and the battery.

The dehumidifier 3 may detect the internal humidity of the energy storage system (ESS) and remove moisture from the internal air of the energy storage system (ESS) to maintain the internal humidity of the energy storage system (ESS) at a constant level.

The dehumidifier 3 is connected to one section of the first cooling unit 1 and may release heat generated during the dehumidification by exchanging heat with the first coolant W1 flowing in the first cooling unit 1.

That is, the dehumidifier 3 may release the heat generated during the dehumidification to the outside by exchanging heat with the first coolant W1 introduced into the radiator 13 without releasing the heat to the inside of the energy storage system (ESS).

The dehumidifier 3 may include a compressor 31 for dehumidification, a condenser 32 for dehumidification, an expansion valve 33 for dehumidification, an evaporator 34 for dehumidification, a drain unit 35, and a fan 36 for dehumidification.

The compressor 31 for dehumidification may compress the gaseous dehumidifying refrigerant to form the gaseous dehumidifying refrigerant into a high temperature and high pressure state.

The condenser 32 for dehumidification may be connected to one section of the 1-1th coolant flow line 14.

The condenser 32 for dehumidification may cool the gaseous dehumidifying refrigerant compressed by the compressor 31 for dehumidification by exchanging heat with the first coolant W1 to form the gaseous dehumidifying refrigerant into a liquid state.

Accordingly, the heat generated during the dehumidification may be released to the outside through the radiator 13 without being introduced into the energy storage system (ESS).

The expansion valve 33 for dehumidification may reduce the pressure of the cooled liquid dehumidifying refrigerant and control the flow rate of the discharged dehumidifying refrigerant to form the dehumidifying refrigerant into a wet vapor state.

The evaporator 34 for dehumidification may remove moisture from the air by heat-exchanging the dehumidifying refrigerant in the reduced wet vapor state with the air flowing inside the energy storage system (ESS), and form the dehumidifying refrigerant into the gaseous state.

The drain unit 35 may discharge moisture separated from the air by the evaporator 34 for dehumidification to the outside of the energy storage system (ESS).

The fan 36 for dehumidification may be arranged in front of the evaporator for dehumidification 34.

The fan 36 for dehumidification may introduce the air flowing inside the energy storage system (ESS) into the evaporator 34 for dehumidification, and discharge the dried air passing through the evaporator 34 for dehumidification back into the energy storage system (ESS).

For example, the compressor 31 for dehumidification, the condenser 32 for dehumidification, the expansion valve 33 for dehumidification, and the evaporator 34 for dehumidification may be connected to each other through the refrigerant flow lines for dehumidification through which the dehumidifying refrigerant flows.

In this way, according to the embodiment of the present disclosure, the cooling method may be selectively switched according to the outdoor temperature of the energy storage system (ESS), so the battery B and the power conversion system (PCS) having different management temperatures may be efficiently cooled.

In addition, only when the outdoor temperature of the energy storage system (ESS) is a certain temperature or less, the coolant is cooled using the outside air, and when the outdoor temperature of the energy storage system (ESS) exceeds the certain temperature, the coolant is cooled by a refrigerant using electricity, so the energy consumed during the cooling may be used efficiently.

In addition, since the natural cooling method that cools the coolant using the outside air and the power cooling method that cools the coolant by circulating the refrigerant using electric energy can be used in combination, the overall specifications of the thermal management system can be reduced compared to when the power cooling method is used alone, so the maintenance cost and the amount of electric energy consumed may be significantly reduced.

In addition, when the outdoor temperature of the energy storage system (ESS) is a specific temperature or lower, the coolant is cooled using only the outside air without using the electric energy, so that the energy storage system may be environmentally friendly.

In addition, since the heat generated in the dehumidifier 3 is not discharged into the energy storage system (ESS), but is discharged to the outside using the first coolant W1 that is continuously circulated without being affected by the outdoor temperature of the energy storage system (ESS), the continuous use of the dehumidifier 3 is possible, so the internal humidity of the energy storage system (ESS) may be maintained at a constant level, and the temperature inside the energy storage system (ESS) may be prevented from rising due to the heat generated by the dehumidifier 3.

In addition, since the radiator 13 and the condenser 232 for cooling the coolant are arranged in a series or parallel structure depending on the installation environment, the space inside the energy storage system (ESS) may be efficiently utilized.

According to an embodiment of the present disclosure, by selectively switching the cooling method according to the outdoor temperature of the energy storage system, it is possible to efficiently cool the battery and the power conversion system having different management temperatures.

In addition, only when the outdoor temperature of the energy storage system is a specific temperature or less, the external air is used to cool the coolant, and when the external temperature of the energy storage system exceeds a specific temperature, the power is used to cool the coolant with the refrigerant, so the energy consumed during cooling may be used efficiently.

In addition, since the natural cooling method that cools the coolant using the outside air and the power cooling method that cools the coolant by circulating the refrigerant using electric energy can be used in combination, the overall specifications of the thermal management system can be reduced compared to when the power cooling method is used alone, so the maintenance cost and the amount of electric energy consumed may be significantly reduced.

In addition, when the outdoor temperature of the energy storage system is a specific temperature or lower, the coolant is cooled using only the outside air without using the electric energy, so that the energy storage system may be environmentally friendly.

In addition, since the heat generated in the dehumidifier is not discharged into the energy storage system, but is discharged to the outside using the first coolant that is continuously circulated without being affected by the outdoor temperature of the energy storage system, the continuous use of the dehumidifier is possible, so the internal humidity of the energy storage system may be maintained at a constant level, and the temperature inside the energy storage system may be prevented from rising due to the heat generated by the dehumidifier.

In addition, since the radiator and the condenser for cooling a coolant are arranged in a series or parallel structure depending on the installation environment, the space inside the energy storage system may be efficiently utilized.

The effects according to the present disclosure are not limited to the contents exemplified above, and more diverse effects are included in the present disclosure.

Although the embodiments of the present disclosure have been described in more detail with reference to the attached drawings, the present disclosure is not necessarily limited to these embodiments, and may be variously modified and implemented within a scope that does not depart from the technical spirit of the present disclosure. Accordingly, exemplary embodiments disclosed in the present disclosure are not to limit the spirit of the present disclosure, but are to describe the spirit of the present disclosure. The scope of the present disclosure is not limited to these exemplary embodiments. Therefore, it should be understood that the above-mentioned embodiments are exemplary in all aspects but are not limited thereto. The scope of the present disclosure should be interpreted by the following claims and it should be interpreted that all spirits equivalent to the following claims fall within the scope of the present disclosure.

Therefore, other implementations, other embodiments, and equivalents of the claims are within the scope of the following claims.

What is claimed is:

1. A thermal management system for an energy storage system that selectively switches a cooling method according to an outdoor temperature of the energy storage system to cool a battery and a power conversion system (PCS) arranged inside the energy storage system, the thermal management system comprising:
a first cooling unit configured to cool the battery and the power conversion system, or the power conversion system, with a first coolant cooled using outside air; and
a second cooling unit configured to cool the battery with a second coolant cooled using a refrigerant.

2. The thermal management system of claim 1, wherein when an outdoor temperature of the energy storage system is a predetermined temperature or lower, the first cooling unit sequentially cools the battery and the power conversion system by circulating the first coolant, and
when the outdoor temperature of the energy storage system exceeds the predetermined temperature, the first cooling unit cools the power conversion system by circulating the first coolant, and the second cooling unit cools the battery by circulating the refrigerant and the second coolant.

3. The thermal management system of claim 2, wherein the first cooling unit includes:
a first coolant storage tank in which the first coolant is stored;
a first discharge pump that discharges the first coolant stored in the first coolant storage tank;
a radiator that cools the first coolant introduced thereinto using the outside air;
a 1-1th coolant flow line that supplies the first coolant discharged from the first discharge pump to the radiator;
a 1-2th coolant flow line that supplies the first coolant cooled by the radiator to the battery or the power conversion system;
a 1-3th coolant flow line that supplies the first coolant that has passed through the battery to the power conversion system; and
a 1-4th coolant flow line that supplies the first coolant that has passed through the power conversion system to the first coolant storage tank.

4. The thermal management system of claim 3, wherein the 1-2th coolant flow line supplies the first coolant to the battery when the outdoor temperature of the energy storage system is the predetermined temperature or lower, and supplies the first coolant to the power conversion system when the outdoor temperature of the energy storage system exceeds the predetermined temperature.

5. The thermal management system of claim 4, wherein the 1-2th coolant flow line includes:
a first supply pipe that is connected to the radiator;
a first branch pipe that is branched in a first direction from the first supply pipe and connected to the battery and the second cooling unit;
a second branch pipe that is branched in a second direction from the first supply pipe and connected to the power conversion system; and
a 1-1th coolant supply control valve that is arranged between the first supply pipe, the first branch pipe, and the second branch pipe, and supplies the first coolant to the first branch pipe or the second branch pipe according to the outdoor temperature of the energy storage system.

6. The thermal management system of claim 5, wherein the 1-3th coolant flow line includes:
a second supply pipe that connects the battery and the power conversion system; and
a 1-2th coolant supply control valve that is arranged in the second supply pipe and opens/closes the second supply pipe according to the outdoor temperature of the energy storage system.

7. The thermal management system of claim 5, wherein the second cooling unit includes:
a second coolant storage tank in which the second coolant is stored;
a second discharge pump that discharges the second coolant stored in the second coolant storage tank;
a heat exchanger that cools the second coolant introduced thereinto using a refrigerant;
a 2-1th coolant flow line that supplies the second coolant discharged from the second discharge pump to the heat exchanger;
a 2-2th coolant flow line that supplies the second coolant cooled by the heat exchanger to the battery through the first branch pipe; and
a 2-3th coolant flow line that supplies the second coolant that has passed through the battery to the second coolant storage tank.

8. The thermal management system of claim 7, wherein the heat exchanger includes:
a compressor for cooling a coolant that compresses a gaseous refrigerant to form a high temperature and high pressure state;
a condenser for cooling a coolant that cools the gaseous refrigerant compressed by the compressor for cooling a coolant using the outside air to form the gaseous refrigerant into a liquid state;
an expansion valve for cooling a coolant that decompresses the cooled liquid refrigerant and controls a flow rate of the discharged refrigerant to form the refrigerant in a wet vapor state;
a chiller for cooling a coolant that heat-exchanges the refrigerant in the decompressed wet vapor with the second coolant flowing inside to cool the second coolant and form the refrigerant into a gaseous state;
a first refrigerant flow line that supplies the refrigerant discharged from the compressor for cooling a coolant to the condenser for cooling a coolant;
a second refrigerant flow line that supplies the refrigerant discharged from the condenser for cooling a coolant to the expansion valve for cooling a coolant;
a third refrigerant flow line that supplies the refrigerant discharged from the expansion valve for cooling a coolant to the chiller for cooling a coolant; and
a fourth refrigerant flow line that supplies the refrigerant discharged from the chiller for cooling a coolant to the compressor for cooling a coolant.

9. The thermal management system of claim 8, wherein the radiator and the condenser for cooling a coolant are arranged to overlap each other and are simultaneously cooled by the outside air.

10. The thermal management system of claim 9, wherein the 2-2th coolant flow line includes:
a third supply pipe that connects the heat exchanger and the first branch pipe; and
a 2-1th coolant supply control valve that is arranged between the third supply pipe and the first branch pipe and opens/closes the third supply pipe according to the outdoor temperature of the energy storage system.

11. The thermal management system of claim 10, wherein the 2-3th coolant flow line includes:
a fourth supply pipe that connects the battery and the second coolant storage tank; and
a 2-2th coolant supply control valve that is arranged in the fourth supply pipe and opens/closes the fourth supply pipe according to the outdoor temperature of the energy storage system.

12. The thermal management system of claim 3, further comprising:
a dehumidifier that controls an internal humidity of a specific zone of the energy storage system,
wherein the dehumidifier is connected to one section of the first cooling unit, and releases heat generated during dehumidification by exchanging heat with the first coolant flowing in the first cooling unit.

13. The thermal management system of claim 12, wherein the dehumidifier includes:
a compressor for dehumidification that compresses a gaseous dehumidifying refrigerant to form a high temperature and high pressure state;
a condenser for dehumidification that is connected to one section of the 1-1th coolant flow line and cools the gaseous dehumidifying refrigerant compressed by the compressor for dehumidification by exchanging heat with the first coolant to form the gaseous dehumidifying refrigerant into a liquid state;
an expansion valve for dehumidification that decompresses the cooled liquid dehumidifying refrigerant and controls a flow rate of the discharged dehumidifying refrigerant to form the dehumidifying refrigerant in a wet vapor state;
an evaporator for dehumidification that heat exchanges the dehumidifying refrigerant in the decompressed wet vapor state with air flowing inside the energy storage system to remove moisture from the air, and form the dehumidifying refrigerant into a gaseous state;
a drain unit that discharges the moisture separated from the air by the evaporator for dehumidification to the outside of the energy storage system; and
a fan for dehumidification that is arranged in front of the evaporator for dehumidification and introduces air flowing inside the energy storage system into the evaporator for dehumidification, and discharges dried air passing through the evaporator for dehumidification back into the inside of the energy storage system.

14. The thermal management system of claim 12, wherein the specific zone where the dehumidifier controls the internal humidity is a zone including at least one of a PCS room equipped with the power conversion system or a battery room equipped with the battery.

15. The thermal management system of claim 2, wherein the predetermined temperature is set to a temperature lower than the management temperature of the battery.
